(19) United States
(12) Patent Application Publication
(10) Pub. No.: US 2025/0362880 A1
(43) Pub. Date: Nov. 27, 2025

(54) Primitive Polynomial-based Multi-bit Linear-feedback Shift Register (LFSR) Counter

(71) Applicant: Microsoft Technology Licensing, LLC, Redmond, WA (US)

(72) Inventors: Tama Gal, Haifa (IL); Yevgeny Yankilevich, Tirat Carmel (IL); Gil Savir, Haifa (IL)

(21) Appl. No.: 18/674,568

(22) Filed: May 24, 2024

(51) Int. Cl. G06F 7/60; G06F 1/03; H03K 19/21

(52) U.S. Cl. CPC G06F 7/60; G06F 1/03; H03K 19/21

(57) ABSTRACT

A multi-bit linear-feedback shift register (LFSR) counter comprises a plurality of flip-flops serially coupled to one another with a separate flip-flop for each bit of a number of bits of the multi-bit counter, wherein each flip-flop has an individual binary value that, when combined with binary values of the other flip-flops, generates a unique sequence of bits representative of a unique state for the plurality of flip-flops; exclusive-or (XOR) logic between a pair of flip-flops based upon, at least in part, a plurality of taps for a primitive polynomial defined for the number of bits; and a look-up read-only table (LUT) mapping the unique sequence of bits generated by the plurality of flip-flops to a sequential decimal count value based upon, at least in part, an initial unique sequence of bits generated by the plurality of flip-flops.

### BACKGROUND

In the field of digital hardware design, traditional binary counters structured with serially connected “Full Adders” have been a standard. However, these counters encounter substantial limitations in scenarios involving wide counters or high-frequency operations. More specifically, Full Adder counters are subject to propagation delay issues and inefficient area consumption. For instance, significant propagation delays arise due to a carry ripple effect in serial logic. As the counter length increases, the time it takes for a carry to propagate through all stages of the counter increases, leading to timing closure issues in high-speed circuits. Regarding area consumption, the design of a conventional counter with Full Adder circuits necessitates a larger area on the chip as each bit requires relatively large combinational logic per bit of the counter. This becomes more pronounced as the counter length increases, making it less feasible for compact hardware designs. As such, traditional binary counters are less efficient in modern digital applications where greater speeds and efficient hardware real estate usage are performance critical.

### BRIEF DESCRIPTION OF THE DRAWINGS

FIG. 1 is a diagrammatic view of a multi-bit linear-feedback shift register (LFSR) counter according to an example implementation;

FIG. 2 is a diagrammatic view of an integrated circuit including a multi-bit LFSR counter system with a plurality of multi-bit LFSR counters and a shared look-up table (LUT) according to an example implementation; and

FIG. 3 is a diagrammatic view of an integrated circuit including a multi-bit LFSR counter system with a plurality of multi-bit LFSR counters, a shared look-up table (LUT), and a shared random-access memory (RAM) according to an example implementation.

Like reference symbols in the various drawings indicate like elements.

### DETAILED DESCRIPTION OF THE EMBODIMENTS

Implementations of the present disclosure enable efficient counter designs using liner-feedback shift registers in high-speed digital systems (e.g., digital signal processing, telecommunications, cryptography, etc.). For example, a linear-feedback shift register includes a shift register whose input is a linear function of its previous state. As will be described in greater detail below, implementations of the present disclosure describe a multi-bit LFSR counter with exclusive-or logic between a subset of the flip-flops based upon a primitive polynomial defined for the number of bits of the multi-bit LFSR counter.

For example, a primitive polynomial is a polynomial of “n” degree over a finite field of 2ⁿ, that cannot be factored into a polynomial of lower degree over the same finite field, where “n” is the number of bits. In some implementations, the multi-bit LFSR counter includes a flip-flop for each bit and exclusive-or logic between a pair of flip-flops based upon, at least in part, a plurality of taps (i.e., bit positions in the LFSR that affect the next state of bits in the LFSR) for the primitive polynomial defined for the number of bits. In some implementations, for a specific width, the primitive polynomial is selected to minimize the amount of exclusive-or logic required, making the multi-bit LFSR counter significantly more efficient in terms of both space and speed. With this exclusive-or logic and arrangement of flip-flops, the multi-bit LFSR counter generates all non-zero values in a consistent, cyclical set of values to count through, including a non-zero initial value. In some implementations, the multi-bit LFSR counter includes a look-up table (LUT) that maps the unique combination of bits from the plurality of flip-flops to a sequential decimal value. In this manner, the multi-bit LFSR counter includes reduced circuitry and logic compared to the conventional Full Adder binary counter. Additionally, the use of shift register based LFSR counters substantially increases speed and reduces the chip area required compared to conventional Full Adder binary counters.

Implementations of the present disclosure provide adaptable and efficient configurations involving multiple counters. For example and in some implementations, a single look-up table (LUT), that converts the values generated by each multi-bit LFSR counter into corresponding binary values, can be shared by a plurality of multi-bit LFSR counters. This shared usage of a single LUT allows the multi-bit LFSR counter system to be highly efficient and to scale effectively for any number of multi-bit LFSR counters.

The details of one or more implementations are set forth in the accompanying drawings and the description below. Other features and advantages will become apparent from the description, the drawings, and the claims.

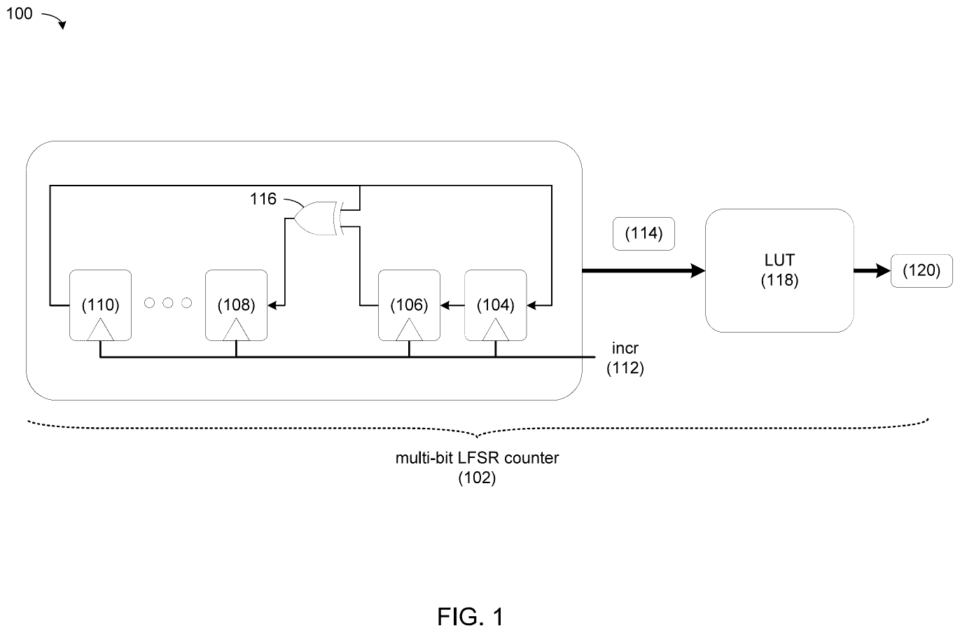

In some implementations and referring also to FIG. 1, an integrated circuit (e.g., integrated circuit 100) and/or an integrated circuit design includes a multi-bit linear-feedback shift register (LFSR) counter. A multi-bit LFSR counter (e.g., multi-bit LFSR counter 102) is a combination of linear-feedback flip-flops and exclusive-or logic for a particular number of bits (i.e., a bitlength) that cycles through a predefined set of unique bits representative of a unique set of values where the next state or combination of bits is a linear function of its previous state or previous combination of bits. For example and in some implementations, multi-bit LFSR counter 102 includes a shift register comprising a plurality of flip-flops (e.g., flip-flops 104, 106, 108, 110). A shift register is a digital circuit (implemented as hardware and/or software circuits) using a cascade of flip-flops where the output of one flip-flop is connected to the input of the next flip-flop. The plurality of flip-flops share a clock or shift signal. In some implementations, flip-flops 104, 106, 108, 110 are serially coupled to one another with a separate flip-flop for each bit of a number of bits of the multi-bit counter (e.g., serially coupled from right to left with the most significant bit on the left-most end and the least significant bit on the right-most end).

In one example and as shown in FIG. 1, the number of bits is fifteen. Accordingly, multi-bit LFSR counter includes fifteen separate flip-flops. For ease of explanation, FIG. 1 shows four of the fifteen flip-flops with ellipses between flip-flops 108 and 110. In this example, flip-flops for each of the bits that are not shown are serially connected (i.e., the output of a previous flip-flop is the input of a next flip-flop without any exclusive-or logic).

In some implementations, each flip-flop has an individual binary value that, when combined with binary values of the other flip-flops, generates a unique sequence of bits representative of a unique non-zero state for the plurality of flip-flops. For example, with each shift or increment signal (e.g., increment signal 112), multi-bit LFSR counter 102 shifts each bit to the left to the next flip-flop and/or through any exclusive-or logic. As shown in FIG. 1, the output of flip-flop 110 associated with the most significant bit is fed back to the input of flip-flop 104 associated with the least significant bit. In some implementations, the combination of the individual binary values of each flip-flop generates a unique sequence of bits representative of a unique state for the plurality of flip-flops. In one example, the bits from the plurality of flip-flops (i.e., the bit value from flip-flop 110 for the most significant bit [15], the bit value from the flip-flops between flip-flop 108 and flip-flop 110 for bits [14:4], the bit value from flip-flop 108 for bit [3], the bit value from flip-flop 106 for bit [2], and the bit value from flip-flop 104 for bit [1]) are concatenated to generate a unique sequence of bits (e.g., unique sequence of bits 114).

In some implementations, multi-bit LFSR counter includes exclusive-or (XOR) logic between a pair of flip-flops based upon, at least in part, a plurality of taps for a primitive polynomial defined for the number of bits. For example, multi-bit LFSR counter 102 includes XOR logic (e.g., XOR logic 116) between a pair of flip-flops (e.g., flip-flops 106, 108) based upon, at least in part, a plurality of taps for a primitive polynomial defined for the number of bits. A primitive polynomial is a polynomial of “n” degree over a finite field of 2ⁿ, that cannot be factored into a polynomial of lower degree over the same finite field and that generates all non-zero values, where n is the number of bits. Continuing with the above example, suppose that the number of bits is fifteen. In this example, a primitive polynomial for the number of bits is determined (e.g., by receiving a selection in an electronic design automation (EDA) tool and/or by obtaining the primitive polynomial from a table of known primitive polynomials for various numbers of bits). Example primitive polynomials, taps, and the period or finite field for each number of bits is provided below in Table 1:

TABLE 1

| Bits (n) | Primitive polynomial | Taps | Period (2ⁿ − 1) |
|---|---|---|---|
| 2 | x² + x + 1 | 11 | 3 |
| 3 | x³ + x² + 1 | 110 | 7 |
| 4 | x⁴ + x³ + 1 | 1100 | 15 |
| 5 | x⁵ + x³ + 1 | 10100 | 31 |
| 6 | x⁶ + x⁵ + 1 | 110000 | 63 |
| 7 | x⁷ + x⁶ + 1 | 1100000 | 127 |
| 8 | x⁸ + x⁶ + x⁵ + x⁴ + 1 | 10111000 | 255 |
| 9 | x⁹ + x⁵ + 1 | 100010000 | 511 |
| 10 | x¹⁰ + x⁷ + 1 | 1001000000 | 1,023 |
| 11 | x¹¹ + x⁹ + 1 | 10100000000 | 2,047 |
| 12 | x¹² + x¹¹ + x¹⁰ + x⁴ + 1 | 111000001000 | 4,095 |
| 13 | x¹³ + x¹² + x¹¹ + x⁸ + 1 | 1110010000000 | 8,191 |
| 14 | x¹⁴ + x¹³ + x¹² + x² + 1 | 11100000000010 | 16,383 |
| 15 | x¹⁵ + x² + 1 | 100000000000010 | 32,767 |

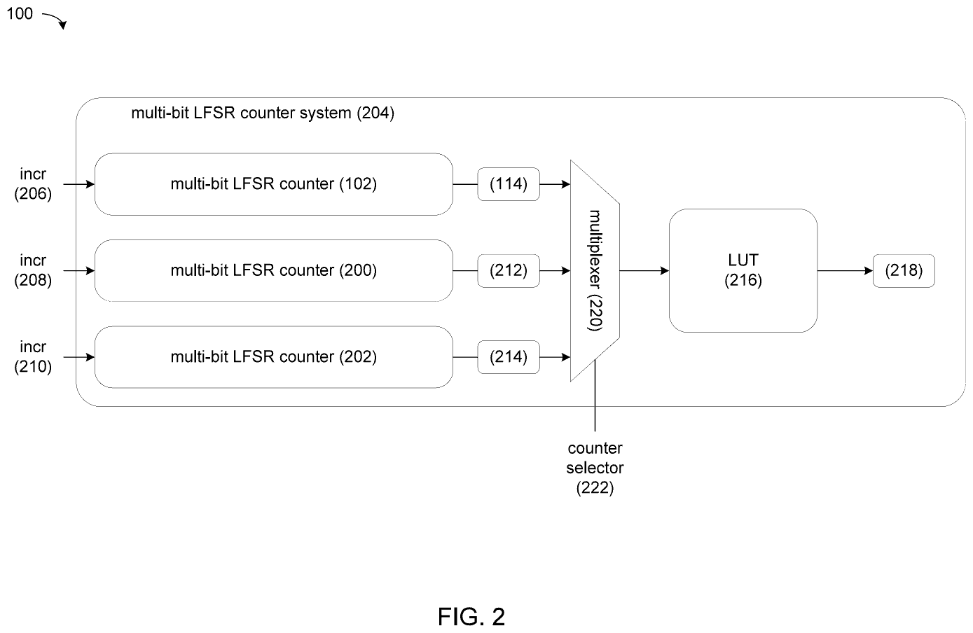

In some implementations, the XOR logic (e.g., XOR logic 116) includes a separate XOR gate for each pair of taps of the primitive polynomial defined for the number of bits. As shown in Table 1, the tap values are the bit positions in the LFSR that affect the next state of bits in the LFSR. For example and referring again to FIG. 1, for fifteen bits, the primitive polynomial is x¹⁵+x²+1 with taps of the second bit and the fifteenth bit (e.g., a pair of taps formed from the second and fifteenth bits). Accordingly and in this example, an XOR gate is positioned after the flip-flop associated with the second bit (e.g., flip-flop 106) with inputs from the flip-flops corresponding to the taps (e.g., flip-flop 110 and flip-flop 106) and an output provided to flip-flop 108. As shown in FIG. 2, the use of XOR gates in multi-bit LFSR counter 102 is minimal (relative to other conventional counter solutions) and strategically deployed based on the chosen primitive polynomial. In this example, the most-significant bit of the unique sequence of bits is always “1” and does not require an XOR gate.

In some implementations, the unique sequence of bits generated by the plurality of flip-flops correspond to (2ⁿ)−1 unique values as determined by the primitive polynomial and the initial value. For example and as discussed above, the primitive polynomial implemented in a LFSR counter includes a finite field or period of unique values that multi-bit LFSR counter 102 sequences through by shifting bits from right to left and performing XOR logic operations where XOR logic 116 is positioned between flip-flops as shown in FIG. 1. Accordingly, multi-bit LFSR counter 102 governed by a primitive polynomial generates a unique sequence of bits with each increment signal (e.g., increment signal 112), cycling through (2ⁿ)−1 states. In some implementations, the unique sequence of bits excludes the all-zero state (i.e., where all bits are zero). After incrementing through its period of unique sequences of bits, multi-bit LFSR counter 102 cyclically returns to the initial value, ensuring a continuous, predictable output.

In some implementations, multi-bit LFSR counter includes a look-up read-only table (LUT) mapping the unique sequence of bits generated by the plurality of flip-flops to a sequential decimal count value based upon, at least in part, an initial unique sequence of bits generated by the plurality of flip-flops. A look-up table (LUT) (e.g., LUT 118) is a digital circuit (implemented in hardware and/or software) that maps input signals (i.e., combination of input bit(s)) to a corresponding output signal (i.e., combination of output bit(s)). In some implementations, LUT 118 is programmed (e.g., during integrated circuit design and/or during fabrication of multi-bit LFSR counter 102) with unique sequences of bits from the period for the primitive polynomial defined for multi-bit LFSR counter 102 and corresponding sequential decimal count values. For instance and as discussed above, as the period or finite field of the primitive polynomial for multi-bit LFSR counter 102 includes non-zero values that multi-bit LFSR counter 102 cycles through, these values do not equate to sequential decimal count values used by counters. Accordingly, LUT 118 maps these unique sequences of bits generated by multi-bit LFSR counter 102 (e.g., unique sequence of bits 114) to sequential decimal count values (e.g., sequential decimal count value 120).

A sequential decimal count value is a decimal number that is counted or incremented. For example, suppose the period or finite field of the primitive polynomial for multi-bit LFSR counter 102 is 32,767 as shown in Table 1. In this example, LUT 118 maps an initial unique sequence of bits to “0”, a next unique sequence of bits to “1”, the next unique sequence of bits to decimal value “2”, and so on until each unique sequence of bits is mapped to a corresponding decimal value. While an example of an increment of one has been provided for the corresponding sequential decimal count values, it will be appreciated that any sequential or increment value of decimal values may be used within the scope of the present disclosure.

In some implementations, LUT 118 maps any unique sequence of bits 114 generated by the shift register to a corresponding sequential decimal count value by first determining an initial unique sequence of bits. For example, as multi-bit LFSR counter 102 cycles through a period of unique sequences of bits, the initial unique sequence of bits is a non-zero value. For instance, if a zero value is used within multi-bit LFSR counter 102, multi-bit LFSR counter 102 will simply shift bit values of zero through the shift register without entering a new state. Accordingly, LUT 118 maps the initial unique sequence of bits (e.g., unique sequence of bits 114) to an initial decimal count value (e.g., sequential decimal count value 120).

In some implementations, a multi-bit linear-feedback shift register (LFSR) counter system includes a plurality of multi-bit LFSR counters. Referring also to FIG. 2 and in some implementations, multiple multi-bit LFSR counters (e.g., multi-bit LFSR counters 102, 200, 202) can be combined to form multi-bit LFSR counter system 204. In some implementations, each multi-bit LFSR counter includes the same initial value. Each multi-bit LFSR counter has independent increment signals (e.g., increment signals 206, 208, 210). In some implementations, multi-bit LFSR counter 102 generates a first unique sequence of bits (e.g., first unique sequence of bits 114); multi-bit LFSR counter 200 generates a second unique sequence of bits (e.g., second unique sequence of bits 212); and multi-bit LFSR counter 202 generates a third unique sequence of bits (e.g., third unique sequence of bits 214). In this manner, multiple, independent counters provide respective unique sequences of bits that can be processed separately.

In some implementations, the multi-bit LFSR counter system includes a shared look-up read-only table (LUT) mapping the unique sequence of bits generated by each multi-bit LFSR counter to a sequential decimal count value based upon, at least in part, an initial unique sequence of bits generated by each respective multi-bit LFSR counter. For example, multi-bit LFSR counter system 204 includes a single, shared LUT (e.g., LUT 216) that maps each respective unique sequence of bits (e.g., unique sequence of bits 114, 212, 214) to a respective corresponding sequential decimal count value (e.g., sequential decimal count value 218). While FIG. 2 shows a single sequential decimal count value 218, it will be appreciated that LUT 216 generates sequential decimal count values for each respective unique sequence of bits.

In some implementations, the multi-bit LFSR counter system includes a multiplexer that selects a respective multi-bit LFSR counter from which a respective unique sequence of bits is provided to the shared LUT to generate a respective sequential decimal count value. A multiplexer (e.g., multiplexer 220) is a digital circuit (implemented in hardware and/or software) that selects between several input signals and forwards the selected input to a single output line. As shown in FIG. 2, multiplexer 220 includes a count selector signal (e.g., counter selector signal 222) that provides a selection (e.g., binary representation) of a particular multi-bit LFSR counter to pass to LUT 216 for generating respective sequential decimal count value 218.

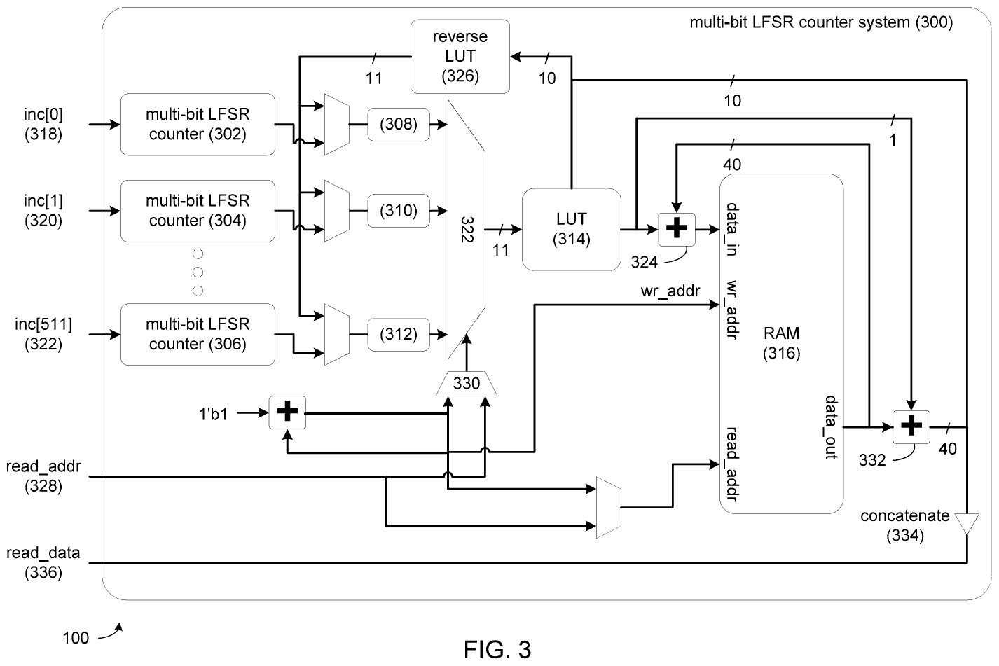

Referring also to FIG. 3 and in some implementations, a multi-bit LFSR counter system (e.g., multi-bit LFSR counter system 300) includes a plurality of multi-bit LFSR counters (e.g., multi-bit LFSR counters 302, 304, 306) that each generate a respective unique sequences of bits (e.g., unique sequence of bits 308, 310, 312), a LUT (e.g., LUT 314), and random access memory (RAM) (e.g., RAM 316) that stores the sequential decimal count value. RAM 316 is a form of electronic computer memory that can be read and changed in any order, typically used to store working data and machine code. RAM 316 allows data items to be read or written in almost the same amount of time irrespective of the physical location of data inside the memory. In some implementations, RAM 316 takes the form of integrated circuit (IC) chips with MOS (metal-oxide-semiconductor) memory cells.

In some implementations, RAM 316 stores a predefined number of most significant bits of the sequential decimal count value and the plurality of flip-flops generate a predefined number of least significant bits of the sequential decimal count value. In one example, RAM 316 is a buffer used for counting LFSR overlaps in order to wrap around each multi-bit LFSR counter. As shown in FIG. 3, multi-bit LFSR counter system 300 is a cached RAM counter using LFSR counters. In this example, multi-bit LFSR counter system 300 is a fifty-bit counter system with five-hundred twelve individual counters. As shown in FIG. 3, the five-hundred twelve counters are represented by multi-bit LFSR counters 302, 304, 306 with increment signals 318, 320, 322 for each counter. In this example, an eleven-bit LFSR counter is used for employing update-logic. Instead of using overflow-bit registers as in conventional counter systems, an update operation is done using shared LUT 314 by converting the unique sequence of bits to a sequential decimal value or a sequential binary value. In this example, the resulting eleventh binary bit (the counterpart of an overflow-bit for a ten-bit count) is added to its corresponding memory entry in RAM 316. For example, adder circuit 324 adds the eleventh binary bit to the stored forty most significant bits in RAM 316 for the respective multi-bit LFSR counter. When the eleventh bit is a “1”, the forty most significant bits are incremented by “1”. When the eleventh bit is a “0”, no change is made or an increment of “0” is performed on the forty most significant bits from RAM 316.

Using reverse LUT 326, the sequential decimal value or sequential binary value is converted back to a unique sequence of bits of the LFSR. As shown in FIG. 3, a single LUT and a single reverse LUT perform these mappings for each of the five-hundred twelve multi-bit LFSR counters. The resulting ten-bit unique sequence of bits is written to the respective multi-bit LFSR counter.

When an external counter read is performed for a particular count value (e.g., using the signal read_addr 328), the corresponding multi-bit LFSR counter is selected using multiplexer 330 and its unique sequence of bits is converted to an eleven-bit sequential decimal value or sequential binary value. The eleventh bit is added to the corresponding memory entry using adding circuit 332, and the resulting forty most significant bits are concatenated (e.g., using concatenate circuit 334) to the ten least significant bits generated by LUT 314 and provided on read_data 336. In this manner, employing multi-bit LFSR counters instead of conventional binary counters results in faster logic and less-expensive logic for counting systems.

For example and referring also to Table 2 below, an example is shown where least-significant bit counters are implemented using binary counters and multi-bit LFSR counters (i.e., 1024 counters of 10-bits each in binary representation) where the multi-bit LFSR counter us based on the primitive polynomial of x¹¹+x⁹+1. In this example, the circuits are synthesized on an FPGA with a 250-megahertz (MHz) clock.

TABLE 2

| Counter Type | ALMs needed |
|---|---|
| Binary | 10412.5 |
| Multi-bit LFSR | 8184.8 |

As shown above in Table 2, multi-bit LFSR counters used 8,184.8 ALMs while conventional binary counters required 10,412.5 ALMs. Accordingly, using multi-bit LFSR counters, the number of ALMs required is reduced by over 20%.

### System Overview:

In some implementations, multi-bit LFSR counter may be implemented as an entirely hardware embodiment, an entirely software embodiment (including firmware, resident software, micro-code, etc.) or an embodiment combining software and hardware aspects that are all generally be referred to herein as a “circuit,” “module,” “process,” or “system.”

For example and in some implementations, multi-bit LFSR counter is a software component and/or hardware component of an integrated circuit (e.g., integrated circuit 100). Integrated circuits (ICs) are the building blocks for many electronic devices. An integrated circuit is a miniature electronic circuit that is fabricated onto a piece of semiconductor material, typically silicon. The fabrication process involves the deposition of various materials, such as silicon dioxide and metal, onto the semiconductor substrate, followed by etching and doping steps to create the desired circuitry. This process allows for the integration of thousands to billions of electronic components, such as transistors, diodes, and resistors, onto a single chip. In some implementations, the multi-bit LFSR counter of the present disclosure may be formed from a combination of hardware and/or software components within an integrated circuit.

In some implementations, multi-bit LFSR counter is a software component and/or hardware component designed and implemented on a Field Programmable Gate Array. Field-Programmable Gate Arrays (FPGAs) are a type of integrated circuit that offers flexibility and reconfigurability in hardware design. Unlike Application-Specific Integrated Circuits (ASICs), which are designed for specific applications and fabricated with a fixed configuration, FPGAs can be programmed and reprogrammed after manufacturing to implement different logic functions and designs. FPGAs consist of an array of programmable logic blocks interconnected by configurable routing resources. Designers can use hardware description languages like Verilog or VHDL to describe the desired functionality, which is then synthesized into configuration files that define the routing and logic connections within the FPGA. This flexibility makes FPGAs suitable for prototyping, rapid development, and applications where adaptability or customization is required. As will be described in greater detail below, the multi-bit LFSR counter may be defined using a hardware description language and implemented using various programmable logic blocks to perform the relevant functions. As such, it will be appreciated that the multi-bit LFSR counter of the present disclosure may be instantiated in software using various components that perform the same function as flip-flops, shift registers, exclusive-or logic, look-up tables, RAM, and/or multiplexers without actually including hardware versions of flip-flops, shift registers, exclusive-or logic, look-up tables, RAM, and/or multiplexers.

Application-Specific Integrated Circuits (ASICs), on the other hand, are custom-designed integrated circuits optimized for a specific application or set of tasks. ASICs are created through a process called Application-Specific Integrated Circuit Design (ASIC Design), which involves designing the circuit layout and functionality to meet the specific requirements of the target application. ASICs can offer performance advantages over general-purpose processors or FPGAs because they are tailored to the specific task at hand, leading to improved speed, power efficiency, and area utilization. ASICs can be further classified into two main categories: Full-Custom ASICs and Semi-Custom ASICs. Full-Custom ASICs involve the manual design of every transistor and interconnect in the circuit, offering the highest level of optimization but requiring significant design expertise and development time. Semi-Custom ASICs utilize pre-designed and pre-verified functional blocks, such as standard cells or IP cores, to reduce design time and complexity while still providing a high degree of customization and performance optimization. In some implementations, the multi-bit LFSR counter of the present disclosure may be designed as a part of a Full-Custom ASIC or a Semi-Custom ASIC.

### General:

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be used. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object-oriented programming language. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet.

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general-purpose computer/special purpose computer/other programmable data processing apparatus, such that the instructions, which execute via the processor of the computer or other programmable data processing apparatus, create means for implementing the functions/acts specified in the flowchart and/or block diagram block or blocks.

These computer program instructions may also be stored in a computer-readable memory that may direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the figures may illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, not at all, or in any combination with any other flowcharts depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A multi-bit linear-feedback shift register (LFSR) counter comprising:
a plurality of flip-flops serially coupled to one another with a separate flip-flop for each bit of a number of bits of the multi-bit counter, wherein each flip-flop has an individual binary value that, when combined with binary values of the other flip-flops, generates a unique sequence of bits representative of a unique state for the plurality of flip-flops;
exclusive-or (XOR) logic between a pair of flip-flops based upon, at least in part, a plurality of taps for a primitive polynomial defined for the number of bits; and
a look-up read-only table (LUT) mapping the unique sequence of bits generated by the plurality of flip-flops to a sequential decimal count value based upon, at least in part, an initial unique sequence of bits generated by the plurality of flip-flops.

2. The multi-bit LFSR counter of claim 1, wherein the initial unique sequence of bits is a non-zero value.

3. The multi-bit LFSR counter of claim 1, wherein the primitive polynomial defined for the number of bits is a polynomial of n degree over a finite field of 2ⁿ, that cannot be factored into a polynomial of lower degree over the same finite field and that generates all non-zero values, where n is the number of bits.

4. The multi-bit LFSR counter of claim 1, wherein the unique sequence of bits generated by the plurality of flip-flops correspond to (2ⁿ)−1 unique values as determined by the primitive polynomial, where n is the number of bits.

5. The multi-bit LFSR counter of claim 1, wherein the XOR logic includes a separate XOR gate for each pair of taps of the primitive polynomial defined for the number of bits.

6. The multi-bit LFSR counter of claim 1, further comprising:
a random-access memory (RAM) that stores the sequential decimal count value.

7. The multi-bit LFSR counter of claim 6, wherein the RAM stores a predefined number of most significant bits of the sequential decimal count value and the plurality of flip-flops generate a predefined number of least significant bits of the sequential decimal count value.

8. An integrated circuit including a multi-bit linear-feedback shift register (LFSR) counter system, the multi-bit LFSR counter system comprising:
a plurality of multi-bit LFSR counters, wherein each multi-bit LFSR counter includes:
a plurality of flip-flops serially coupled to one another with a separate flip-flop for each bit of a number of bits of the multi-bit counter, wherein each flip-flop has an individual binary value that, when combined with binary values of the other flip-flops, generates a unique sequence of bits representative of a unique state for the plurality of flip-flops;
exclusive-or (XOR) logic between a pair of flip-flops based upon, at least in part, a plurality of taps for a primitive polynomial defined for the number of bits;
a shared look-up read-only table (LUT) mapping the unique sequence of bits generated by each multi-bit LFSR counter to a sequential decimal count value based upon, at least in part, an initial unique sequence of bits generated by each respective multi-bit LFSR counter; and
a multiplexer that selects a respective multi-bit LFSR counter from which a respective unique sequence of bits is provided to the shared LUT to generate a respective sequential decimal count value.

9. The multi-bit LFSR counter system of claim 8, wherein the initial unique sequence of bits for each respective multi-bit LFSR counter is a non-zero value.

10. The multi-bit LFSR counter system of claim 8, wherein the primitive polynomial defined for the number of bits is a polynomial of n degree over a finite field of 2ⁿ, that cannot be factored into a polynomial of lower degree over the same finite field and that generates all non-zero values, where n is the number of bits.

11. The multi-bit LFSR counter system of claim 8, wherein the unique sequence of bits generated by each multi-bit LFSR counter include (2ⁿ)−1 unique values as determined by the primitive polynomial, where n is the number of bits.

12. The multi-bit LFSR counter system of claim 8, wherein the XOR logic for each multi-bit LFSR counter includes a separate XOR gate for each combination of non-zero coefficients of the primitive polynomial defined for the number of bits.

13. The multi-bit LFSR counter system of claim 8, further comprising:
a random-access memory (RAM) that stores the respective sequential decimal count value for each multi-bit LFSR counter.

14. The multi-bit LFSR counter system of claim 13, wherein the RAM stores a predefined number of most significant bits of the respective sequential decimal count value and the respective multi-bit LFSR counter generates a predefined number of least significant bits of the respective sequential decimal count value.

15. An integrated circuit including a multi-bit linear-feedback shift register (LFSR) counter system, the multi-bit LFSR counter system comprising:
a plurality of multi-bit LFSR counters, wherein each multi-bit LFSR counter includes:
a plurality of flip-flops serially coupled to one another with a separate flip-flop for each bit of a number of bits of the multi-bit counter, wherein each flip-flop has an individual binary value that, when combined with binary values of the other flip-flops, generates a unique sequence of bits representative of a unique state for the plurality of flip-flops;
exclusive-or (XOR) logic between a pair of flip-flops based upon, at least in part, a plurality of taps for a primitive polynomial defined for the number of bits;
a shared look-up read-only table (LUT) mapping the unique sequence of bits generated by each multi-bit LFSR counter to a sequential decimal count value based upon, at least in part, an initial unique sequence of bits generated by each respective multi-bit LFSR counter;
a multiplexer that selects a respective multi-bit LFSR counter from which a respective unique sequence of bits is provided to the shared LUT to generate a respective sequential decimal count value; and
a random-access memory (RAM) that stores the respective sequential decimal count value for each multi-bit LFSR counter.

16. The multi-bit LFSR counter system of claim 15, wherein the initial unique sequence of bits is a non-zero value.

17. The multi-bit LFSR counter system of claim 15, wherein the primitive polynomial defined for the number of bits is a polynomial of n degree over a finite field of 2ⁿ, that cannot be factored into a polynomial of lower degree over the same finite field and that generates all non-zero values, where n is the number of bits.

18. The multi-bit LFSR counter system of claim 15, wherein the unique sequence of bits generated by each multi-bit LFSR counter include (2ⁿ)−1 unique values as determined by the primitive polynomial, where n is the number of bits.

19. The multi-bit LFSR counter system of claim 15, wherein the XOR logic for each multi-bit LFSR counter includes a separate XOR gate for each combination of non-zero coefficients of the primitive polynomial defined for the number of bits.

20. The multi-bit LFSR counter system of claim 19, wherein the RAM stores a predefined number of most significant bits of the respective sequential decimal count value and the respective multi-bit LFSR counter generates a predefined number of least significant bits of the respective sequential decimal count value.
